(19) United States
(12) Patent Application Publication
(10) Pub. No.: US 2014/0146259 A1
(43) Pub. Date: May 29, 2014

(54) LCD DEVICE, ARRAY SUBSTRATE, AND METHOD FOR MANUFACTURING THE ARRAY SUBSTRATE

(71) Applicant: SHENZHEN CHINA STAR OPTOELECTRONICS TECHNOLOGY CO., LTD, Shenzhen (CN)

(72) Inventors: Chengcai Dong, Shenzhen (CN); Jehao Hsu, Shenzhen (CN); Juanning Dang, Shenzhen (CN)

(73) Assignee: SHENZHEN CHINA STAR OPTOELECTRONICS TECHNOLOGY CO., LTD, Shenzhen (CN)

(21) Appl. No.: 13/806,812

(22) PCT Filed: Dec. 4, 2012
(86) PCT No.: PCT/CN2012/085834

§ 371 Date: Dec. 24, 2012

(30) Foreign Application Priority Data
Nov. 27, 2012 (CN) 201210487352.5

(51) Int. Cl. G02F 1/1362; H01L 27/12; G02F 1/1333

(52) U.S. Cl. CPC G02F 1/136286; G02F 1/133345; H01L 27/124; H01L 27/1259
USPC 349/43; 257/59; 438/34

(57) ABSTRACT

The present disclosure provides a liquid crystal display device, an array substrate, and a method for manufacturing the array substrate. The array substrate includes a glass substrate, gate scan lines formed on the glass substrate, and a pixel electrode. An edge of the pixel electrode has an overlapping region with the gate scan lines, and the pixel electrode and the gate scan lines form a parasitic capacitance in the overlapping region. The overlapping region between the pixel electrode and the gate scan lines is configured with at least one protection layer that reduces the parasitic capacitance.

### TECHNICAL FIELD

The present disclosure relates to the field of a liquid crystal display (LCD), and more particularly to an LCD device, an array substrate, and a method for manufacturing the array substrate.

### BACKGROUND

A thin film transistor liquid crystal display (TFT-LCD) has various characteristics such as having a small volume, lower power consumption, and being non-radiative so that the TFT-LCD plays a leading role in the present flat panel display (FPD) market. Components of the TFT-LCD are formed via an array substrate being oppositely arranged on a color film substrate.

As shown from FIG I to FIG. 3, a glass substrate 100 of the array substrate are configured with data lines 115, gate scan lines 110, a thin film transistor (TFT) 140 and a pixel electrode 130, for example. A parasitic capacitance structure on a gate forms a parasitic capacitance via an overlapping region of a cover layer between the pixel electrode and a last gate scan line, which increases aperture ratio of a LCD panel. However, the parasitic capacitance becomes capacitance load of the gate scan lines, which increases resistance-capacitance (RC) delay of signals of the gate scan lines and causes image flicker of the LCD device.

### SUMMARY

In view of the above-described problems, the aim of the present disclosure is to provide an LCD device, an array substrate, and a method for manufacturing the array substrate with the advantages of signal delay of the gate scan lines

The aim of the back light module of the present disclosure is achieved by the following technical scheme: An array substrate of a liquid crystal display (LCD) device comprises a glass substrate, gate scan lines formed on the glass substrate, and a pixel electrode. An insulating layer is layered on the gate scan lines. An edge of the pixel electrode has an overlapping region with the gate scan lines, and the pixel electrode and the gate scan lines form a parasitic capacitance in the overlapping region. The overlapping region between the pixel electrode and the gate scan lines is configured with at least one protection layer that reduces the parasitic capacitance.

In one example, the protection layer is an a-Si layer. The a-Si layer has low dielectric coefficient.

In one example, the a-Si layer is layered on the insulating layer. An a-Si layer of the TFT and the a-Si layer of the protection layer are simulatenously formed in same process, therefore a etching process does not need to add again.

In one example, the a-Si layer of the protection layer and the a-Si layer of the TFT of the array substrate belong to a same layer. An a-Si layer of the TFT and the a-Si layer of the protection layer are simulatenously farmed in same process.

In one example, the pixel electrode is made of indium tin oxide (ITO). The ITO is a transparent electric conduction material, which can increase transmittance of the LCD panel.

A liquid crystal display (LCD) device comprises the above-mentioned the array substrate.

A method for manufacturing the above-mentioned the array substrate, comprising

S1: forming a metal layer on a glass substrate, and forming gate scan lines on the glass substrate by a photolithography process and etching process on the metal layer;

S2: forming an insulating layer and a protection layer on the glass substrate;

S3: forming the array substrate via a layer on the glass substrate and a layer of a pixel electrode, and forming a thin film transistor (TFT) and a pixel electrode on the glass substrate.

In one example, in step S2, the protection layer is an a-Si layer.

In one example, in step S2, the a-Si layer and the a-Si layer of the TFT are simulatenously formed.

In one example, the layer of the pixel electrode is made of indium tin oxide (ITO).

In the present disclosure, the overlapping region between the pixel electrode and the gate scan lines is configured with at least one protection layer that reduces the parasitic capacitance, and a protection is added between the pixel electrode and the gate scan lines, which reduces the parasitic capacitance of the gate scan lines 110 and the pixel electrode 130, further reduces signal delay of the gate scan lines 110, improves display effect of the LCD device, and avoids image flicker.

### BRIEF DESCRIPTION OF FIGURES

FIG. 1 is a structural diagram of a pixel region of an array substrate in prior art; and

FIG. 2 is an enlarged diagram of A of FIG. 1.

FIG. 3 is a sectional view of structure of a overlapping region between a pixel electrode and gate scan lines of the array substrate in prior art;

FIG. 4 is a simplified structural diagram of a first example of the array substrate of the present disclosure;

FIG. 5 is sectional view of structure of the overlapping region between the pixel electrode and gate scan lines of the first example of the array substrate of the present disclosure;

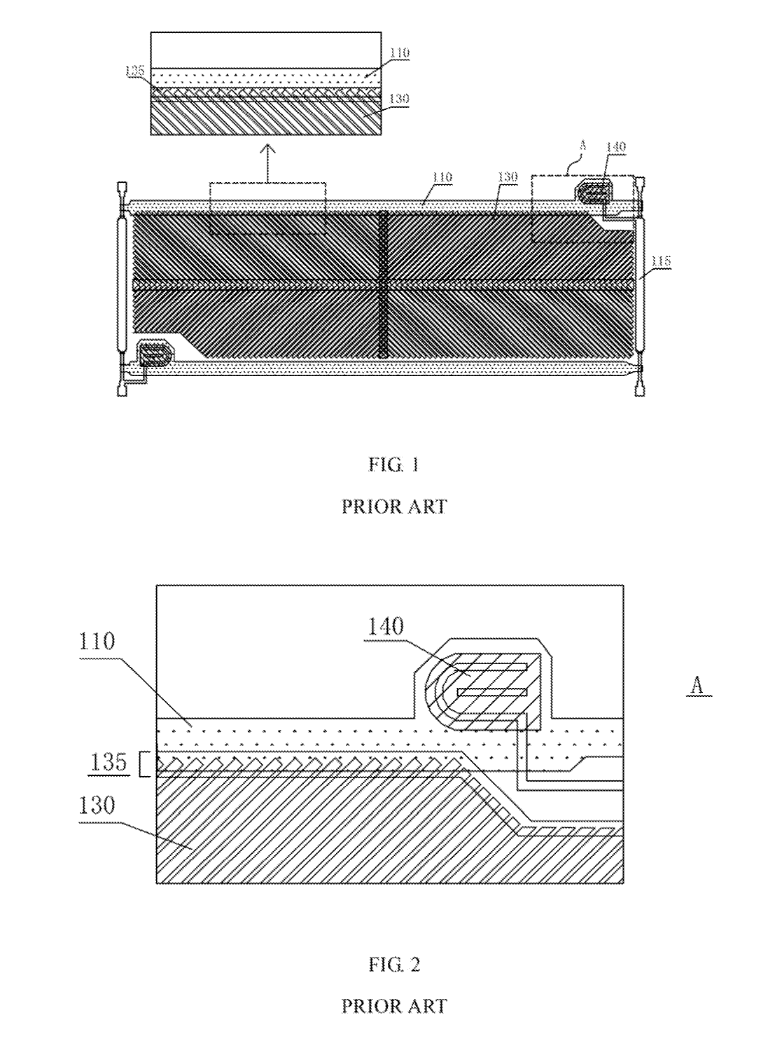

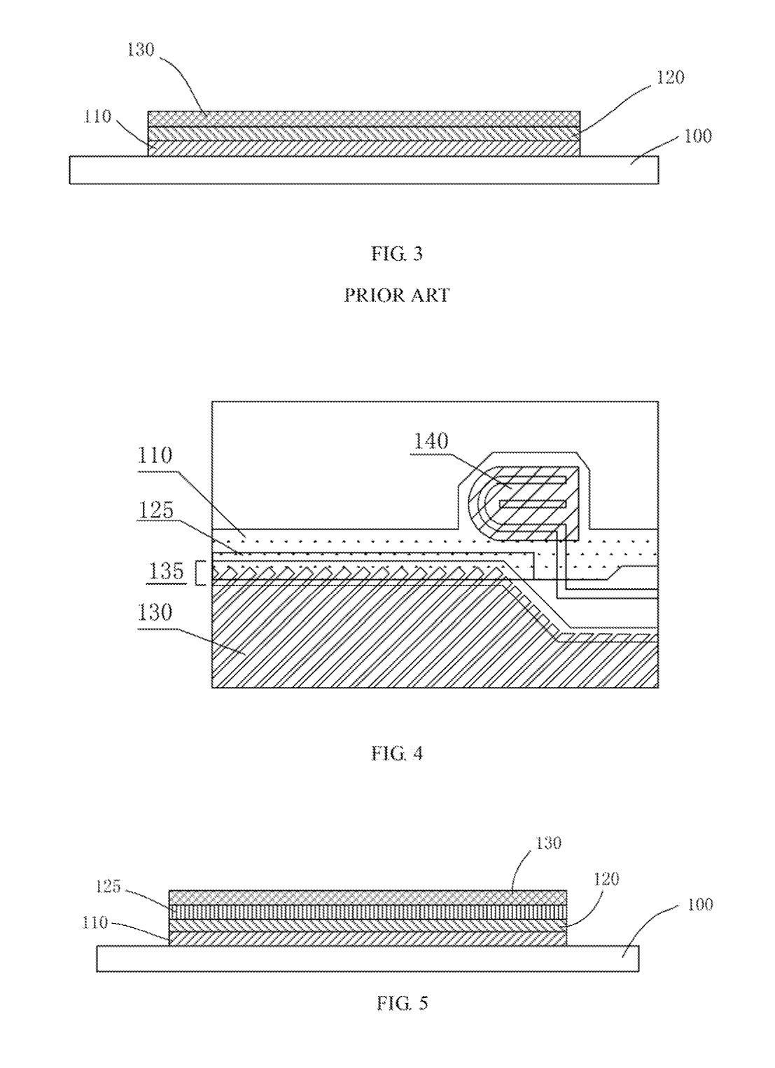

Legends: 100. glass substrate; 110. gate scan lines; 115. Data lines; 120. insulating layer; 130. pixel electrode; 125. protection layer; 135. overlapping region, 140. TFT.

### DETAILED DESCRIPTION

The present disclosure will further be described in detail in accordance with the figures and the examples.

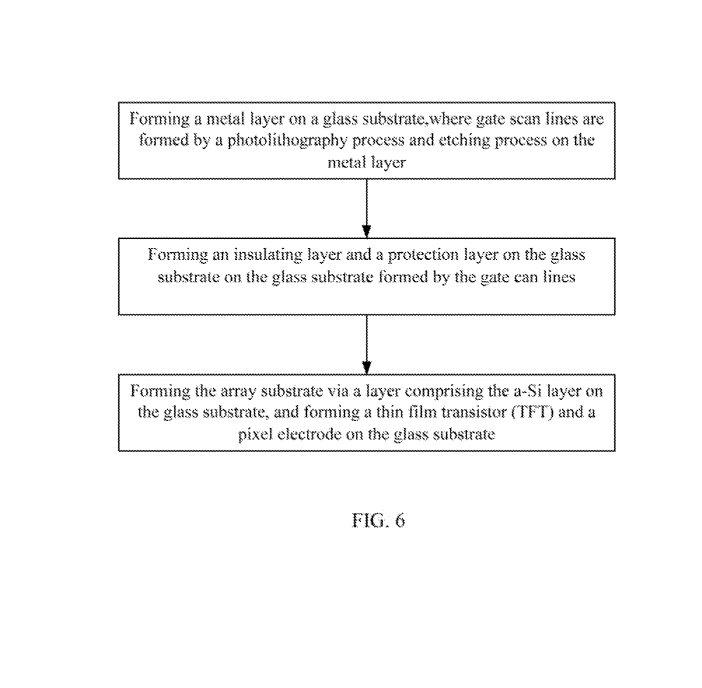

As shown in FIG. 4 and FIG. 5, an array substrate of a liquid crystal display (LCD) device comprises a glass substrate 100, data lines (not shown in figures), and gate scan lines 110. The data lines and the gate scan lines 110 are formed on the glass substrate 100. A pixel area is surrounded by the data lines and the gate scan lines 110. The pixel area configured with a pixel electrode 130 and a thin film transistor (TFT) 140. An edge of the pixel electrode 130 has an overlapping region 135 with the gate scan lines 110. The pixel electrode 130 and the gate scan lines 110 form a parasitic capacitance at the overlapping region 135.

As shown in FIG. 4 and FIG. 5, an insulating layer 120 (not shown in FIG. 4) is layered on the gate scan lines. A protection layer (a-Si layer 125) is layered on the insulating layer 120. The pixel electrode 130 is layered on the a-Si layer 125. The a-Si layer 125 serves as the protection layer between the gate scan lines 110 and the pixel electrode 130 which reduces the parasitic capacitance of the gate scan lines 110 and the pixel electrode 130, further reduces signal delay of the gate scan lines 110, improves display effect of the LCD device, and avoids image flicker.

The a-Si layer 125 and an active layer (a-Si layer) of the TFT of the array substrate belong to a same layer. The a-Si layer 125 is layered on the insulating layer 120. Thus, the active layer (a-Si layer) of the TFT is formed, and simultaneously the a-Si layer is formed in the overlapping region 135 between the pixel electrode 130 and the gate scan lines 110 in a manufacturing process of the array substrate, therefore, which add an unneeded process that forms an organic semiconductor. Optionally, the protection layer (a-Si layer) can be formed before formation of the insulating layer, however, which adds a forming process.

In the example, the pixel electrode is made of indium tin oxide (ITO), where the data lines are also made of the 110. The ITO is a transparent electric conduction material, which can increase transmittance of the LCD panel.

A method for manufacturing an array substrate in the example comprises the following steps:

1. forming a metal layer on a glass substrate, where the metal layer is made of MO, AL, alumel, tungsten-molybdenum alloy, Cr, and Cu for example. The metal layer also is film combination of the above-mentioned materials, where gate scan lines are formed by a photolithography process and etching process on the metal layer.

2. forming an insulating layer on the glass substrate formed by the gate can lines.

3. forming a metal layer again on the glass substrate formed by the insulating layer, and forming data lines by the photolithography process and the etching process

4. forming a thin film transistor (TFT) via a layer based on the above steps comprising an active layer (a-Si layer). When the a-Si layer is etched, the a-Si layer is exposed on an overlapping region between a pixel electrode and the gate scan lines in a masking process.

5. forming the pixel electrode finally.

The present disclosure is described in detail in accordance with the above contents with the specific preferred examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

1. An array substrate of a liquid crystal display (LCD) device comprising:
a glass substrate;
gate scan lines formed on the glass substrate; and
a pixel electrode;
wherein an insulating layer is layered on the gate scan lines; an edge of the pixel electrode has an overlapping region with the gate scan lines; the pixel electrode and the gate scan lines form a parasitic capacitance in the overlapping region:
wherein the overlapping region between the pixel electrode and the gate scan lines is configured with a protection layer that reduces the parasitic capacitance; the protection layer is an a-Si layer layered on the insulating layer; the a-Si layer and an a-Si layer of a thin film transistor (TFT) of the array substrate belonging to a same layer.

2. An array substrate of a liquid crystal display (LCD) device comprising:
a glass substrate;
gate scan lines formed on the glass substrate; and
a pixel electrode;
wherein an insulating layer is layered on the gate scan lines; an edge of the pixel electrode has an overlapping region with the gate scan lines; the pixel electrode and the gate. scan lines form a parasitic capacitance in the overlapping region:;
wherein the overlapping region between the pixel electrode and the gate scan lines is configured with a protection layer that reduces the parasitic capacitance.

3. The array substrate of the LCD device of claim 2, wherein the protection layer is an a-Si layer.

4. The array substrate of the LCD device of claim 3, wherein the a-Si layer is layered on the insulating layer.

5. The array substrate of the LCD device of claim 3, wherein the a-Si layer and an a-Si layer of a thin film transistor (TFT) of the array substrate belong to a same layer,

6. The array substrate of the LCD device of claim 2, wherein the pixel electrode is made of indium Oxide (ITO),

7. A liquid crystal display (LCD) device comprising
an array substrate comprising a glass substrate, gate scan lines formed on the glass substrate, and a pixel electrode;
wherein an insulating layer is layered on the gate scan lines; an edge of the pixel electrode has an overlapping region with the gate scan lines; the pixel electrode and the gate scan lines form a parasitic capacitance in the overlapping region;
wherein the overlapping region between the pixel electrode and the gate scan lines is configured with a protection layer that reduces the parasitic capacitance.

8. The LCD device of claim 7, wherein the protection layer is an a-Si layer.

9. The LCD device of claim 8, wherein the a-Si layer is layered on the insulating layer.

10. The LCD device of claim 8, wherein the a-Si layer and an a-Si layer of a thin film transistor (TFT) of the array substrate belong to a same layer.

11. The LCD device of claim 7, wherein the pixel electrode is made of indium m oxide (ITO).

12. A method for manufacturing the array substrate of the LCD device of claim 2, comprising:
S1: forming a metal layer on a glass substrate, and forming gate scan lines on the glass substrate by a photolithography process and etching process on the metal layer;
S2: forming an insulating layer and a protection layer on the glass substrate;
S3: forming the array substrate via a layer comprising the a-Si layer on the glass substrate, and forming a thin film transistor (TFT) and a pixel electrode on the glass substrate.

13. The method for manufacturing the array substrate of the LCD device of claim 12, in step S2, wherein the protection layer is an a-Si layer.

14. The method for manufacturing the array substrate of the LCD device of claim 13, in the step S2, wherein the a-Si layer and the a-Si layer of the TFT are simultaneously formed.

15. The method for manufacturing the array substrate of the LCD device of claim 12, wherein the layer of the pixel electrode is made of indium tin oxide (ITO).
